(19) United States
(12) Patent Application Publication
(10) Pub. No.: US 2012/0241836 A1
(43) Pub. Date: Sep. 27, 2012

(54) SEMICONDUCTOR DEVICE AND METHOD OF MANUFACTURING SAME

(75) Inventors: Nobuhito KUGE, Tokyo (JP); Masahito Shinohe, Yokkaichi-Shi (JP)

(73) Assignee: KABUSHIKI KAISHA TOSHIBA, Tokyo (JP)

(21) Appl. No.: 13/338,723

(22) Filed: Dec. 28, 2011

(30) Foreign Application Priority Data
Mar. 24, 2011 (JP) 2011-066362

(51) Int. Cl. H01L 27/088; H01L 21/28

(52) U.S. Cl. 257/316; 438/593; 257/E21.19; 257/E27.06; 257/E29.3

(57) ABSTRACT

According to one embodiment, a method of manufacturing a semiconductor device including a memory cell transistor in a first region of a substrate and a select gate transistor in a second region of the substrate includes: forming a gate insulating film, a lower gate electrode, an inter-electrode insulating film, an upper gate electrode, and a hard mask on the substrate; forming a groove passing through the hard mask, the upper gate electrode, and the inter-electrode insulating film and reaching the lower gate electrode in the second region; and forming a connection layer having a crystal structure which preferentially has a specific crystal orientation and that electrically connects between the lower gate electrode and the upper gate electrode by being selectively crystal-grown while being subjected to an influence from a crystal structure of the lower gate electrode in the groove

### CROSS REFERENCE TO RELATED APPLICATION

This application is based upon and claims the benefit of priority from prior Japanese Patent Application No. 2011-66362, filed on Mar. 24, 2011, the entire contents of which are incorporated herein by reference.

### FIELD

Embodiments of the present invention relate to a semiconductor device and a method of manufacturing the same.

### BACKGROUND

With further advancement in miniaturization in accordance with the demand to miniaturize a non-volatile semiconductor storage device, the aspect ratio of the height and the width of the gate structure are becoming higher in the gate pattern processing in the manufacturing of the non-volatile semiconductor storage device.

The reason for this is that the coupling ratio (Cr) needs to be raised in order to control a memory cell transistor due to increase in the mutual interference effect by reduction in the distance between the memory cell transistors of the non-volatile semiconductor storage device. In other words, in order to raise the coupling ratio, which is generally expressed as Cr=C_{IPD}/(C_{IPD}+C_{TNL}), the capacity of the inter poly dielectric (IPD) covering a lower gate electrode (floating gate) is to be increased. To this end, the lower gate electrode is made higher to increase the contacting area of the lower gate electrode and the IPD, but this leads to increase in the aspect ratio at the time of the gate pattern processing since the height of the lower gate electrode increases. If the aspect ratio increases, the degree of difficulty in the processing of the gate pattern increases. The increased ratio also causes lowering of the yield due to gate pattern destruction, and the like in the manufacturing process such as cleaning.

In a select transistor of the non-volatile semiconductor storage device and a peripheral transistor positioned in a surrounding circuit region, the lower gate electrode and the upper gate electrode (control gate) are connected to obtain a desired structure while forming with the memory cell transistor. A groove called an EI (Etching Interpoly) is formed in the IPD for such connection. In this case, it is formed using a hard mask made of a thick oxide silicon film. The hard mask will be removed afterwards, but the upper gate electrode and the IPD are processed to form the EI groove while protecting the IPD with the upper gate electrode in advance, and furthermore, a polycrystalline silicon film is formed so as to fill the EI groove and cover the upper gate electrode, which is already formed, so that the IPD will not be eroded and degraded in the removal. Thus, the upper gate electrode needs to have a stacked structure of two layers, the upper gate electrode formed in advance and the polycrystalline silicon film formed thereon. Such a structure is one of the causes of the increase in the aspect ratio at the time of the gate pattern processing.

When forming a metal gate on the upper gate electrode, the metal gate is formed on the upper gate electrode having a stacked structure as described above, and hence the aspect ratio at the time of the gate pattern processing is further increased.

### BRIEF DESCRIPTION OF THE DRAWINGS

FIGS. 1(a) and 1(b) are a plan view of a semiconductor device according to an embodiment;

FIGS. 2(a) and 2(b) are a cross-sectional view of the semiconductor device according to the embodiment;

FIGS. 3 to 17 are cross-sectional views describing steps for manufacturing the semiconductor device according to the embodiment;

FIGS. 18 to 23 are cross-sectional views describing steps for manufacturing a semiconductor device according to a first modification of the embodiment; and

FIGS. 24 to 28 are cross-sectional views (II) describing steps for manufacturing a semiconductor device according to a second modification of the embodiment.

### DETAILED DESCRIPTION

In one embodiment, a method of manufacturing a semiconductor device is a method of manufacturing a semiconductor device including a memory cell transistor in a first region of a substrate, and a select gate transistor in a second region of the substrate, the method including: forming a gate insulating film, a lower gate electrode, an inter-electrode insulating film, an upper gate electrode, and a hard mask on the substrate; forming a groove passing through the hard mask, the upper gate electrode and the inter-electrode insulating film, and reaching the lower gate electrode in the second region of the substrate; and forming a connection layer having a crystal structure which preferentially has a specific crystal orientation and that electrically connects between the lower gate electrode and the upper gate electrode, by being selectively crystal-grown while being subjected to an influence from a crystal structure of the lower gate electrode in the groove.

The embodiment will be hereinafter described with reference to the drawings. It should be recognized that the present invention is not limited to the embodiment. Common reference numerals are denoted on the portions commonly used throughout the drawings and their description will not be repeated. The drawings are schematic diagrams to facilitate the description and the understanding of the embodiment, and the shape, dimension, ratio, and the like may differ from the actual device in some places. The shape, dimension, ratio, and the like may be appropriately changed in a design, in consideration of the following description and the known arts.

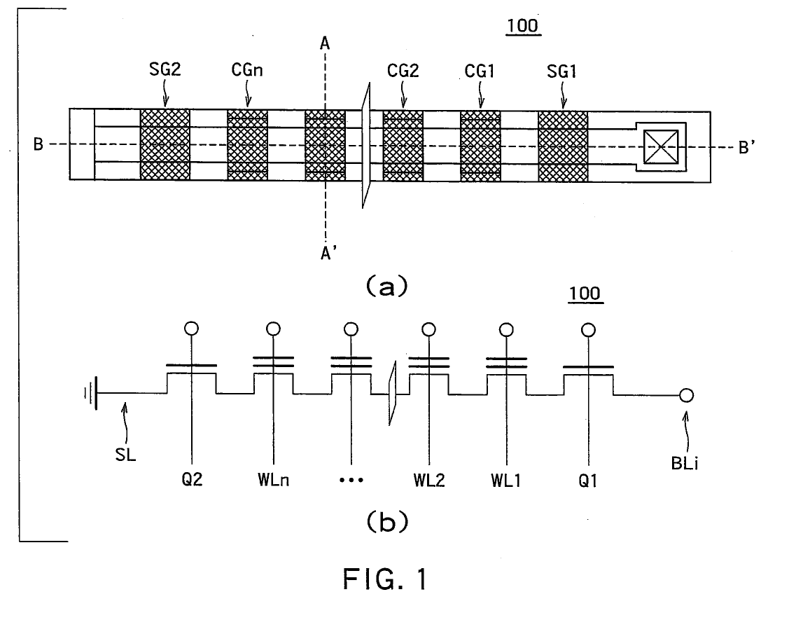

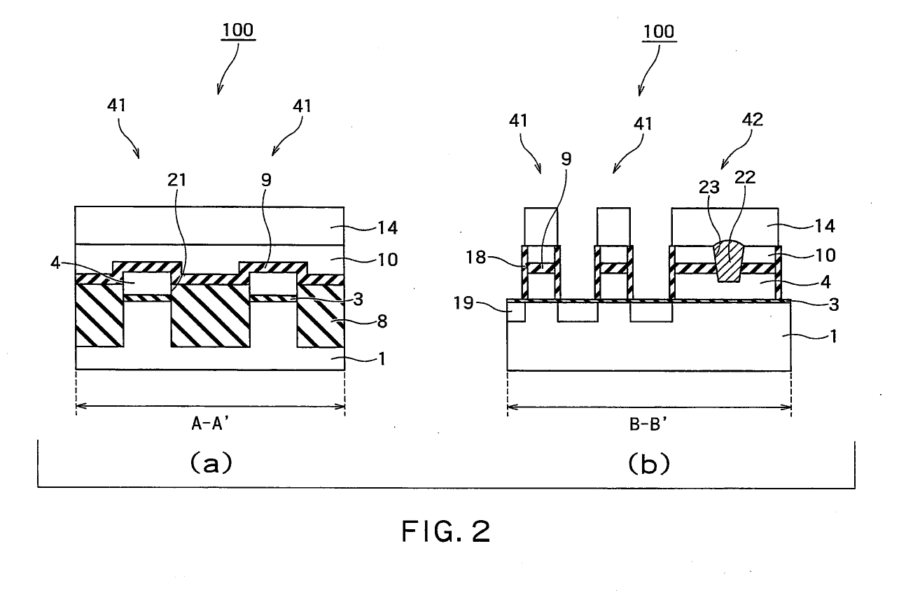

A semiconductor device of the present embodiment will be described using FIGS. 1 and 2. FIGS. 1 and 2 are a plan view and a cross-sectional view, respectively, showing a cell array structure of a NAND type flash memory (semiconductor device) 100 of the embodiment. The NAND type flash memory will be described below by way of example, but the present invention is not limited to such semiconductor device, and may be used in other types of semiconductor devices.

First, as shown in FIGS. 1(a) and 1(b), the NAND type flash memory 100 has a plurality of memory cell transistors CG1 to CGn, including an n-channel MOS FET (Metal Oxide Semiconductor Field Effect Transistor) having an upper gate electrode and a lower gate electrode, connected in series, where a drain on the side of one end is connected to a bit line BLI (i=1, 2, . . . ) through an n-channel MOS transistor SG1 for selection, and a source on the side of the other end is connected to a source line SL through an n-channel MOS transistor SG2 for selection.

The memory cell transistors and the select transistor are formed on the same well substrate. The upper gate electrodes of the memory cell transistors CG1 to CGn are connected to word lines WL1 to WLn continuously arrayed in a row direction. The upper gate electrode of the select transistor SG1 is connected to a selection line Q1 and the upper gate electrode of the select transistor SG2 is connected to a selection line Q2. One end of each word line WL has a connection pad for connecting with a peripheral circuit through a metal wiring and is formed on an element isolation film.

The NAND type flash memory 100 includes a plurality of bit lines BL and a plurality of word lines WL. The bit lines BL are extended in the direction of line B-B′ in FIG. 1(a), and the word lines WL are extended In the direction of line A-A′ in FIG. 1(a).

The NAND type flash memory 100 of the present embodiment will now be described with reference to FIGS. 2(a) and 2(b). FIG. 2(a) is a cross-sectional view of the NAND-type flash memory 100 of the present embodiment taken along line A-A′ in FIG. 1(a), and FIG. 2(b) is a cross-sectional view of the NAND-type flash memory 100 of the present embodiment taken along line B-B′ in FIG. 1(a).

As shown in FIGS. 2(a) and 2(b), the NAND type cell flash memory 100 of the present embodiment includes memory cell transistors 41, a select transistor 42, and a peripheral transistor (not shown) on a silicon substrate 1.

Each memory cell transistor 41 includes a gate insulating film 3 made of, for example, a silicon oxynitride film formed on the silicon substrate 1, a lower gate electrode 4 made of, for example, a polycrystalline silicon film formed on the gate insulating film 3, and an upper gate electrode 10 made of, for example, a polycrystalline silicon film formed on the lower gate electrode 4 through an IPD (inter-electrode insulating film) 9. Furthermore, each memory cell transistor 41 includes a metal gate electrode 14 made from, for example, tungsten or tungsten silicide formed on the upper gate electrode 10. The lower gate electrode 4 is generally referred to as a floating gate, and the upper gate electrode 10 and the metal gate electrode 14 are generally referred to as a control gate.

Each select transistor 42 and each peripheral transistor (not shown) include the gate insulating film 3 made of, for example, a silicon oxynitride film formed on the silicon substrate 1, the lower gate electrode 4 made of, for example, a polycrystalline silicon film formed on the gate insulating film 3, and the upper gate electrode 10 made of, for example, a polycrystalline silicon film formed on the lower gate electrode 4 through the IPD 9. Each select transistor 42 and each peripheral transistor (not shown) also include the metal gate electrode 14 formed on the upper gate electrode 10.

To ensure the operations thereof, each select transistor 42 and each peripheral transistor (not shown) include a connection via (connection layer) 22 that passes through the IPD 9 to electrically connect the lower gate electrode 4 and the upper gate electrode 10 and that is selectively solid-phase grown made from, for example, silicon. The connection via 22 may be made from germanium or a mixture thereof other than silicon, or arsenic, phosphorous, boron, or the like may be doped to lower the contact resistance.

The selective solid-phase growth means crystal-growing while being influenced by the crystal structure of the crystal (lower gate electrode 4 made of polycrystalline silicon film) serving as a base, and forming a crystal structure preferentially having a specific crystalline orientation. Therefore, the connection via 22 has a crystal structure that preferentially has a specific crystalline orientation based on the crystal structure of the lower gate electrode 4. Thus, the interface and the crystal grain boundary are small in the connection via 22, and the interface and the crystal grain boundary are small between the connection via 22 and the lower gate electrode 4.

As apparent from FIGS. 2(a) and 2(b), the upper gate electrode 10 is made of a single layer arranged directly on the IPD 9. Furthermore, as apparent from FIG. 2(b), the upper surface of the connection via 22 is projected from the upper surface of the upper gate electrode 10. The upper surface of the connection via 22 is not limited to such shape, and may be in plane with the upper surface of the upper gate electrode 10.

Furthermore, as apparent from FIG. 2(a), a trench is formed between each memory cell transistor 41, each select transistor 42 and each peripheral transistor (not shown) to separate such transistors, and a buried insulating film 8 is embedded in the trench 21.

As apparent from FIG. 2(b), a silicon dioxide film 18 is formed on the side surfaces of the lower gate electrode 4, the IPD 9, and the upper gate electrode 10. A diffusion layer 19 is formed on the silicon substrate 1 between each memory cell transistor 41, each select transistor 42 and each peripheral transistor (not shown).

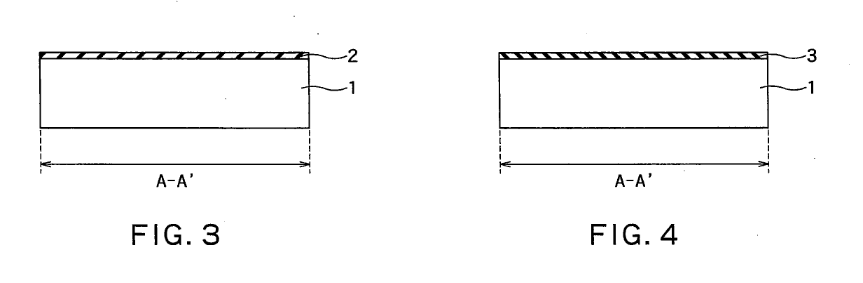

The method of manufacturing the NAND type flash memory 100 of the present embodiment will now be described with reference to FIGS. 3 to 17.

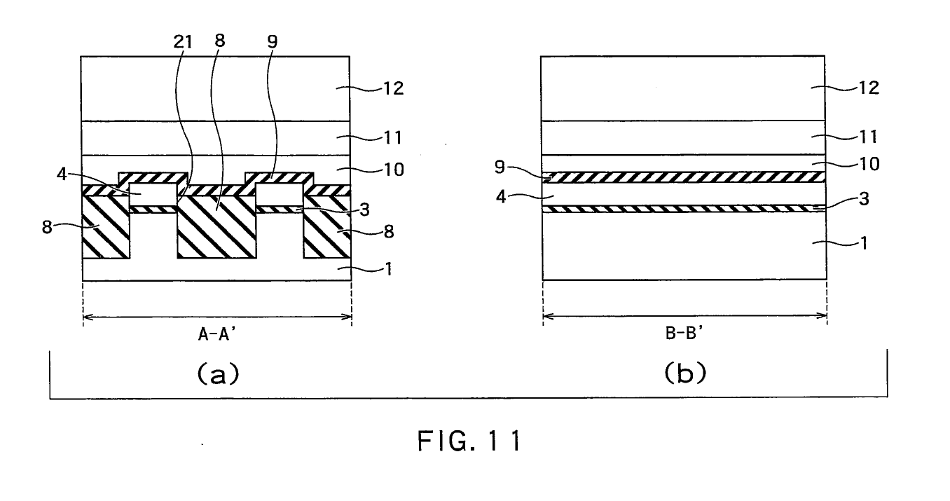

FIGS. 3 to 10 are cross-sectional views corresponding to FIG. 2(a), that is, cross-sectional views corresponding to line A-A′ of FIG. 1(a). To specifically describe the present embodiment, FIGS. 11(a), 12(a), 13(a), 14(a), 15(a), 16(a), and 17(a) are cross-sectional views corresponding to FIG. 2(a), that is, corresponding to line A-A′ of FIG. 1(a); and FIGS. 11(b), 12(b), 13(b), 14(b), 15(b), 16(b), and 17(b) are cross-sectional views corresponding to FIG. 2(b), that is, corresponding to line B-B′ of FIG. 1(a).

As shown in FIG. 3, a silicon dioxide film 2 is formed using a thermal oxidation method on the silicon substrate 1.

As shown in FIG. 4, the silicon dioxide film 2 is azotized using NH₃ gas or the like to form the gate insulating film 3 made of silicon oxynitride film. The gate insulating film 3 is generally referred to as a tunnel oxide film.

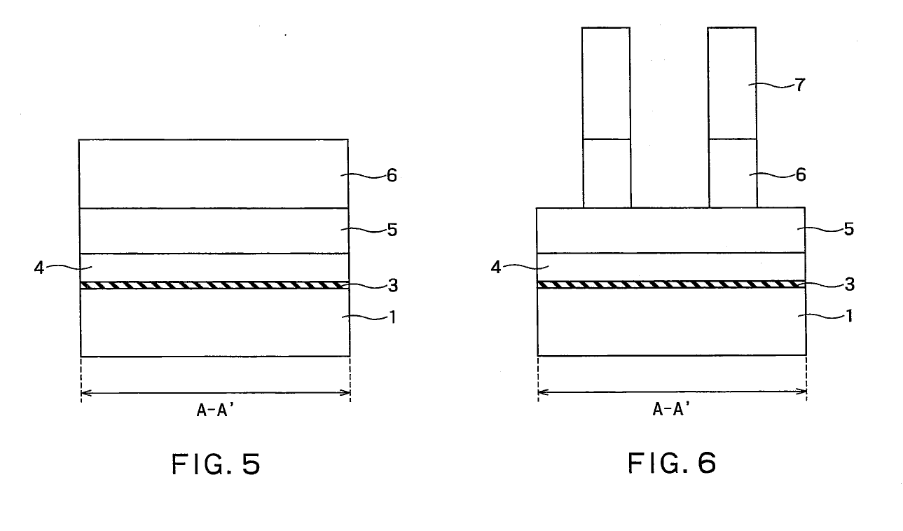

As shown in FIG. 5, the lower gate electrode 4 made of polycrystalline silicon film, a silicon nitride film 5, and an oxide film 6 are sequentially formed using CVD (Chemical Vapor Deposition) method on the gate insulating film 3.

As shown in FIG. 6, a photoresist 7 is applied, the photoresist 7 is patterned using a lithography method, and the oxide film 6 is processed using the patterned photoresist 7 as a mask.

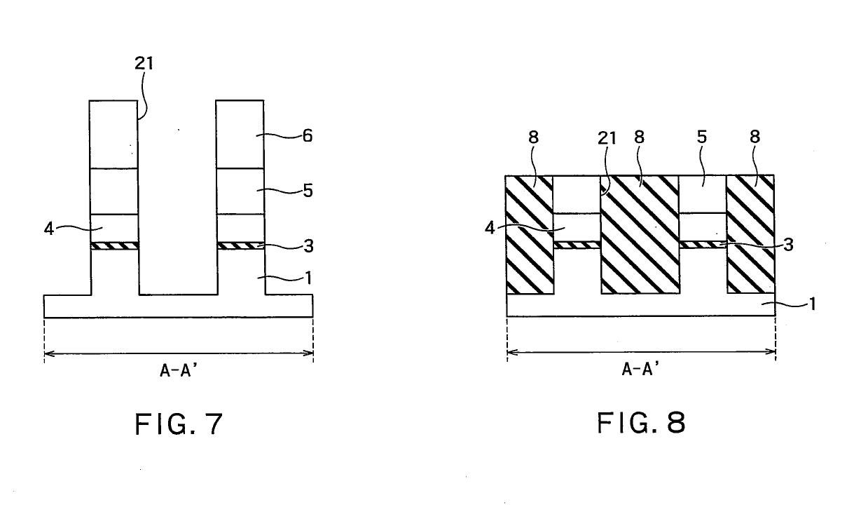

As shown in FIG. 7, the photoresist 7 is removed, and then the oxide film 6, the silicon nitride film 5, the lower gate electrode 4, the gate insulating film 3, and the silicon substrate 1 are processed through RIE (Reactive Ion Etching) method to form the trench 21. The inner wall of the trench 21 formed in the silicon substrate 1 is then oxidized.

After removing the oxide film 6, the buried insulating film 8 is formed to bury the trench 21 through the plasma CVD method to form an element separation structure generally referred to as STI (Shallow Trench Isolation). Furthermore, as shown in FIG. 8, the buried insulating film 8 is polished until the upper surface of the silicon nitride film 5 and the upper surface of the buried insulating film 8 are in plane by CMP (Chemical Mechanical Polishing) method, and the upper surface is flattened.

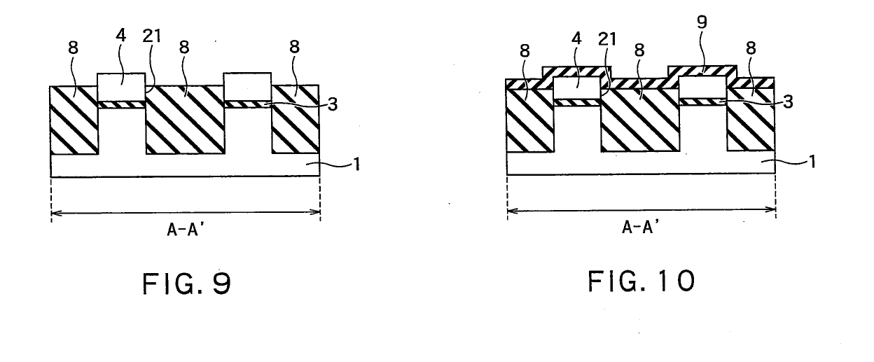

As shown in FIG. 9, the height of the insulating film 8 is lowered with the wet process or the etching process, and thereafter, the wet process is carried out to strip the silicon nitride film 5.

As shown in FIG. 10, the IPD 9 is formed to cover the lower gate electrode 4 and the buried insulating film 8.

The upper gate electrode 10 made of polycrystalline silicon film is then formed on the IPD 9, using LPCVD (Low Pressure Chemical Vapor Deposition) method.

In each select transistor 42 and each peripheral transistor, the upper gate electrode 10 and the lower gate electrode 4 need to be electrically connected. Therefore, in the present embodiment, the connection via 22 for electrically connecting the upper gate electrode 10 and the lower gate electrode 4 is formed, as will be described below.

As shown in FIGS. 11(a) and 11(b), a hard mask 11 and a photoresist 12 are formed on the upper gate electrode 10.

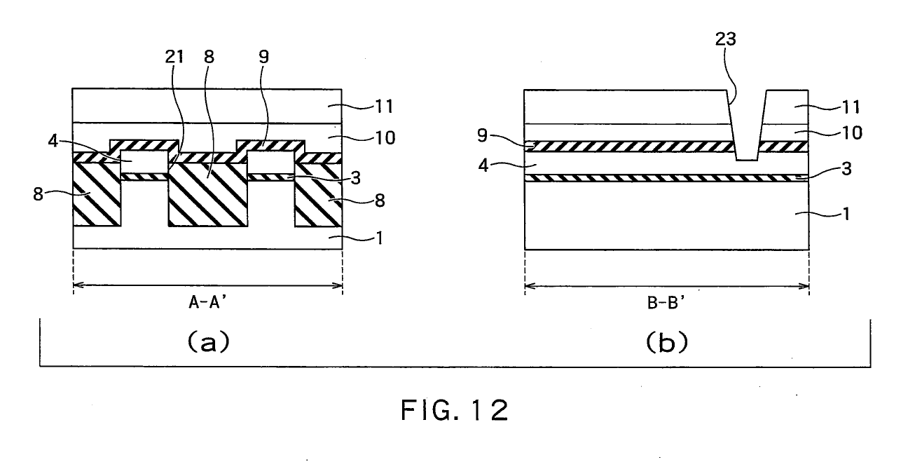

The photoresist 12 is patterned through the lithography method, and the hard mask 11, the upper gate electrode 10, and the IPD 9 are etched through the RIE method, thereby forming an EI groove 23 that passes through the upper gate electrode 10 and the IPD 9 and reaches the lower gate electrode 4. As shown in FIGS. 12(a) and 12(b), the photoresist 12 is stripped using Asher or sulfuric acid-hydrogen peroxide mixture. Furthermore, dilute hydrofluoric acid treatment is carried out to remove processing residual, and the side surfaces and the bottom surface including the lower gate electrode 4 in the EI groove 23 and the side surfaces including the upper gate electrode 10 are hydrogen terminated.

Cleaning is then carried out. When cleaning by water is carried out after the dilute hydrofluoric treatment, a natural oxide film may form on the side surfaces and the bottom surface including the lower gate electrode 4 in the EI groove 23 and the side surfaces including the upper gate electrode 10, and hence alcohol cleaning using isopropanol is desirably carried out. After the cleaning, it is immediately carried into the device where the next step is carried out, and annealing is carried out in vacuum so that a silicon cleaned surface can be exposed on the side surfaces and the bottom surface by the lower gate electrode 4 in the EI groove 23 and the side surfaces by the upper gate electrode 10.

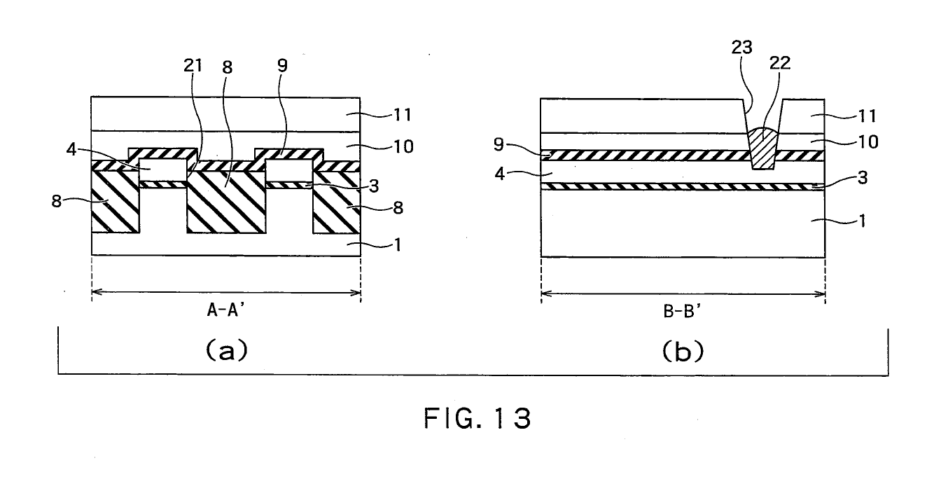

As shown in FIGS. 13(a) and 13(b), the silicon in the EI groove 23 is selectively solid-phase grown to form the connection via 22 such that the upper surface of the connection via 22 is in plane with the upper surface of the upper gate electrode 10 or such that the upper surface of the connection via 22 projects out from the upper surface of the upper gate electrode 10. The formation of the connection via 22 is carried out before stripping the hard mask 11 that was used at the time of forming the EI groove 23 and is covering the upper surface of the upper gate electrode 10 while exposing the EI groove 23. In other words, the silicon is selectively solid-phase grown and formed only in the EI groove 23 while being covered with the hard mask 11. The material of the connection via 22 may be germanium or a mixture thereof other than silicon. Arsenic, phosphorous, boron or the like may be doped in the connection via 22 to lower the contact resistance.

The selective solid-phase growing is generally carried out through the CVD method. The film forming gas that is used is generally Si₂H₂Cl₂, SiHCl₃, or SiCl₄, and such gases are used depending on a growing speed. The growing speed is suppressed when more the Cl is used, and hence the growing speed becomes slower in the order of Si₂H₂Cl₂, SiHCl₃, or SiCl₄.

Furthermore, when doping in the connection via 22, for instance, when forming an n-type silicon connection via 22, PH₃ or AsH₃ is introduced, and when forming a p-type silicon connection via 22, B₂H₆ is introduced as the film forming gas.

Assume here that SiH₂Cl₂ and H₂ that is capable of low temperature growth are used as the film growing gas, and the temperature is set between 700 and 900° C. and the pressure is set in a range from a few dozen to a few hundred Torr for the film forming condition. When such gases are used, reaction expressed with the following reaction formula occurs.

SiH₂Cl₂→SiCl₂+H₂

SiCl₂+H₂→Si+2HCl

As apparent from the above reaction formula, hydrogen chloride (HCl) is generated with the solid-phase growth of the silicon (Si). Silicon (Si) is deposited on the hard mask 11 to form an amorphous silicon film, but the amorphous silicon film on the hard mask 11 is more easily etched than the silicon crystal solid-phase grown in the EI groove 23, and is etched by the generated hydrogen chloride. Therefore, the silicon can be selectively solid-phase grown in the EI groove 23.

For instance, when the silicon having a thickness of 30 nm is to be selectively solid-phase grown in the EI groove 23 as the connection via 22, the film forming time is about one minute in the above condition (in a case where temperature is 750° C.), where the influence on the device element when the selective solid-phase growing is carried out is minor in such extent.

A method of depositing the silicon in the EI groove 23, and then causing migration with high temperature hydrogen annealing to form the connection via 22 can be used instead of carrying out the formation of the connection via 22 by introducing the chlorine based gas at the same time as the selective solid-phase growing. However, the method of introducing the chlorine based gas at the same time as the selective solid-phase growing as described above is preferable in view of the practical aspect and the temperature applied on the device.

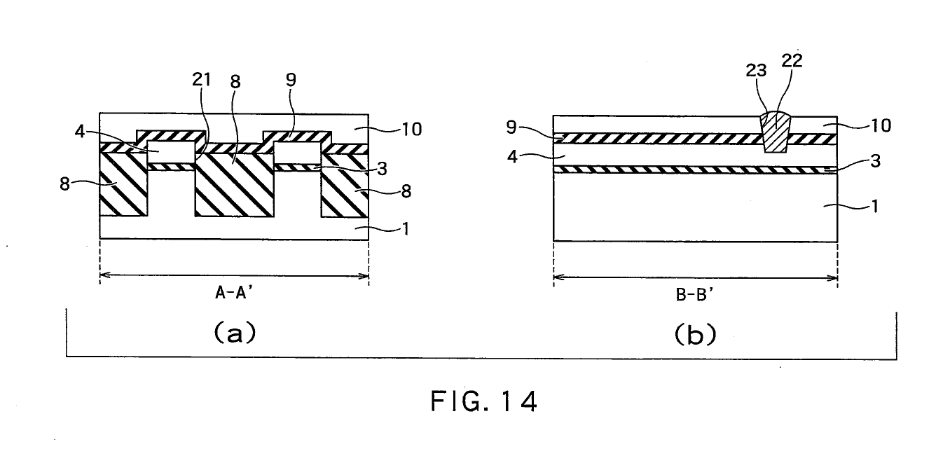

As shown in FIGS. 14(a) and 14(b), the hard mask 11 is stripped after forming the connection via 22.

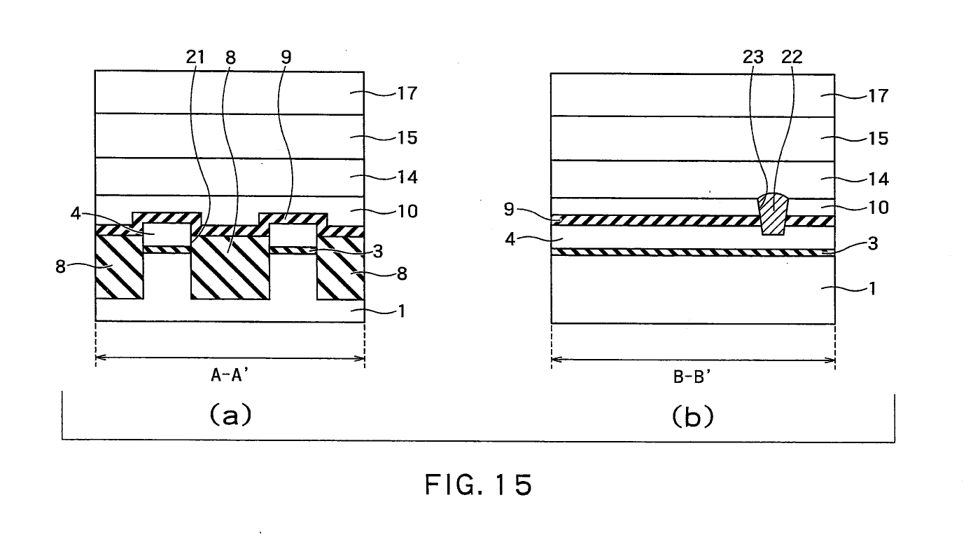

As shown in FIGS. 15(a) and 15(b), the metal gate electrode 14 is formed on the upper gate electrode 10 when simultaneously using the metal gate electrode for the gate electrode. A silicon nitride film 15 is formed through the LPCVD method on the metal gate electrode 14, and a photoresist 17 is applied on the silicon nitride film 15.

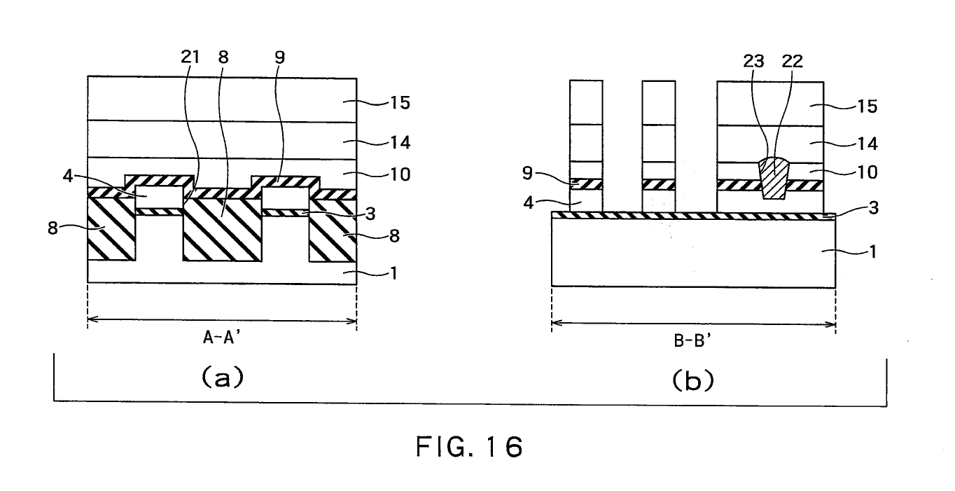

The photoresist 17 is patterned using the lithography method, and furthermore, the patterned photoresist 17 is used as a mask to process the silicon nitride film 15 to a desired pattern. Thereafter, as shown in FIGS. 16(a) and 16(b), the photoresist 17 is removed, and the metal gate electrode 14, the upper gate electrode 10, the IPD 9, and the lower gate electrode 4 are sequentially etched through the RIE (Reactive Ion Etching) method in the vertical direction using the processed silicon nitride film 15 as a mask.

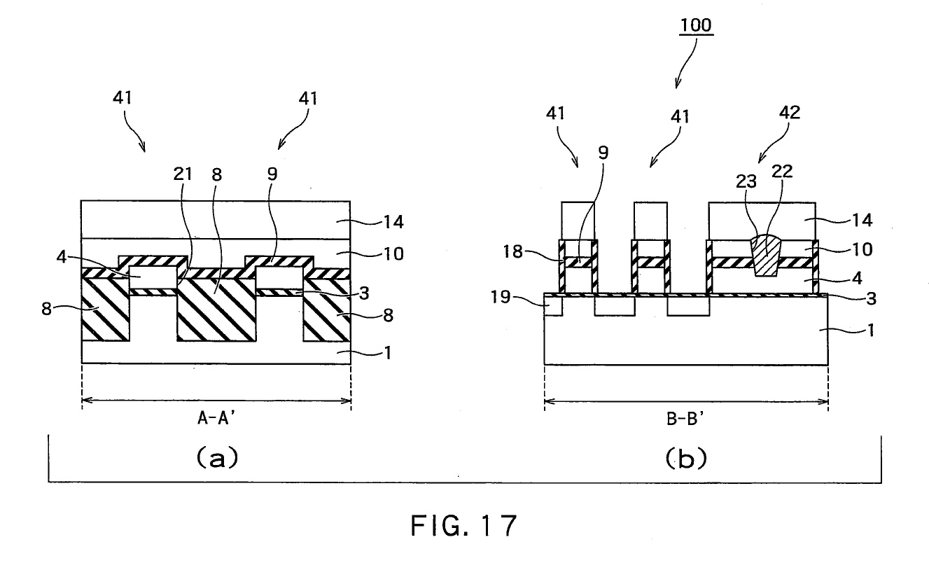

A silicon dioxide film 18 is formed using a thermal oxidation method or a radical oxidation method to recover the damage formed in the IPD 9 by the etching through the RIE method. Generally, such oxidation step is called the post-oxidation step, and the silicon dioxide film 18 formed in this case is referred to as a post-oxide film. Subsequently, as shown in FIGS. 17(a) and 17(b), ion is injected into the silicon substrate 1 using the ion implementation method to form the source and the drain and activated by thermal annealing to form the diffusion layer 19.

According to the present embodiment, in each select transistor 42 and each peripheral transistor of the NAND type flash memory 100, the connection via 22 for electrically connecting the lower gate electrode 4 and the upper gate electrode 10 is formed by forming the EI groove 23 that passes through the IPD 9 and reaches the lower gate electrode 4 from the upper gate electrode, and selectively solid-phase growing the silicon in the EI groove 23, thereby the upper gate electrode 10 can be configured as a single layer. In other words, the upper gate electrode 10 can be avoided from becoming a stacked structure, whereby the aspect ratio at the time of the gate pattern processing can be reduced.

Furthermore, according to the present embodiment, the interface and the crystal grain boundary can be reduced in the connection via 22 as the connection via 22 is formed through the selective solid-phase growing. Furthermore, the interface and the crystal grain boundary can also be reduced between the connection via 22 and the lower gate electrode 4. Therefore, the resistance value of the connection via 22 can be lowered.

The IPD 9 can be avoided from being damaged as the IPD 9 is covered with the upper gate electrode 10 when forming the EI groove 23.

According to the present embodiment, the upper surface of the connection via 22 is in plane with the upper surface of the upper gate electrode 10 or is projected from the upper surface of the upper gate electrode 10. Hence, when using the silicide gate electrode consisting of silicide in place of the metal gate electrode 14, the reaction of the silicide material film and the upper gate electrode 10 in the manufacturing process, which will be described below, can be avoided from being suppressed.

### (First Modification)

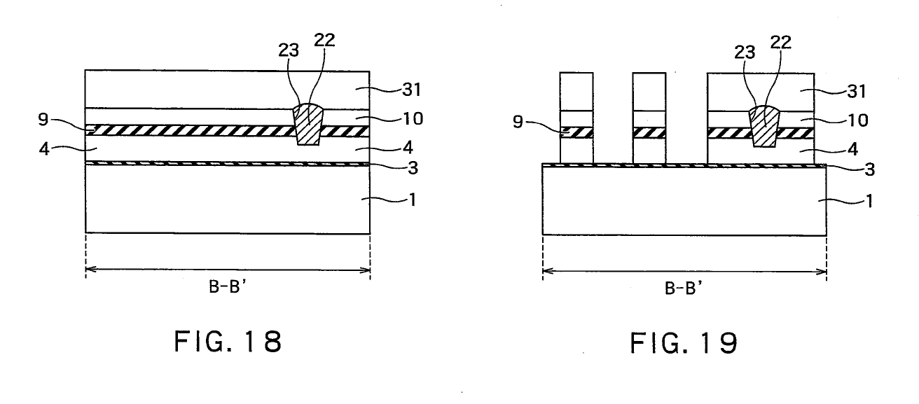

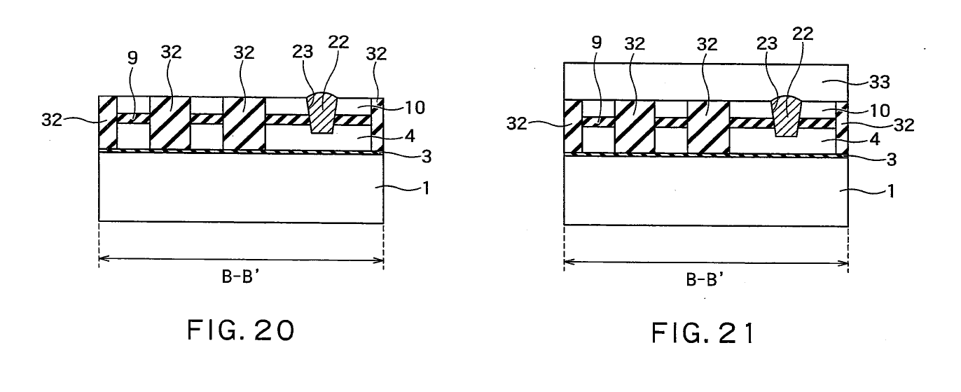

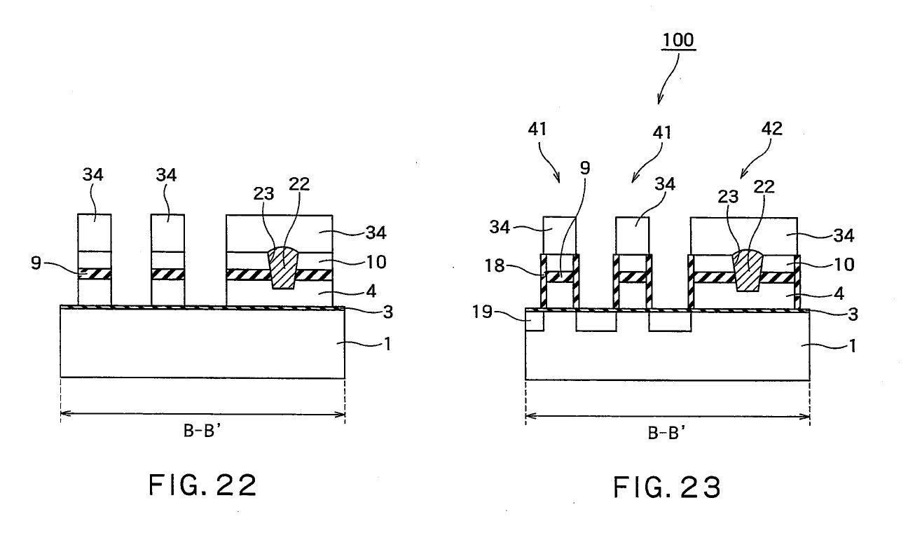

In a first modification of the present embodiment, the NAND type flash memory 100 can be formed in the following manner when using the silicide gate electrode in place of the metal gate electrode 14. The first modification will be described with reference to FIG. 18 to FIG. 23. FIG. 18 to FIG. 24 are cross-sectional views corresponding to FIG. 2(b), that is, line B-B′ of FIG. 1(a). After forming the connection via 22 shown in FIGS. 14(a) and 14(b) in the previously described embodiment, as shown in FIG. 18, the silicon nitride film 31 is formed as a mask on the upper gate electrode 10. Then, the gate structures of the memory cell transistor, the select transistor, and the peripheral transistor are formed along the mask pattern of the silicon nitride film 31, as shown in FIG. 19. The inter-layer insulating film 32 is buried between the gate structures and the silicon nitride film is removed, as shown in FIG. 20. As shown in FIG. 21, the silicide material film 33 of cobalt, nickel, or the like is formed on the upper gate electrode 10 exposed as a result of removing the silicon nitride film. Furthermore, thermal processing is carried out to cause the silicide material film and the upper gate electrode 10 to be reacted, the silicide gate electrode 34 is selectively formed, and the non-reactive silicide material film 33 is removed, thus obtaining a state shown in FIG. 22. The subsequent steps are similar to the previously described embodiment, and hence the description will not be repeated. The NAND type flash memory 100 having a cross-sectional view shown in FIG. 23 is thereby obtained.

When removing the silicon nitride film, the silicon nitride film sometimes get into the recess shaped portion or the like at the upper surface of the connection via 22 and may remains therein when the upper surface of the connection via 22 is formed in the shape of a recess or when a seam is present at the upper surface of the connection via 22. The residual of the remaining silicon nitride film suppresses the reaction of the silicide material film and the upper gate electrode 10.

However, according to the first modification of the present embodiment, the upper surface of the connection via 22 is in plane with the upper surface of the upper gate electrode 10 or is projected out from the upper surface of the upper gate electrode 10. Thus, the residual of the silicon nitride film can be avoided from being generated, and hence the reaction of the silicon material film and the upper gate electrode 10 can be avoided from being suppressed.

In the first modification of the present embodiment, after the EI groove 23 is formed while protecting the IPD 9 with the upper gate electrode 10 in advance, the connection via 22 made from silicon is formed only in the EI groove 23, instead of forming the upper gate electrode having a two-layer stacked structure of the upper gate electrode formed in advance and the polycrystalline silicon film formed thereon by burying the polycrystalline silicon in the EI groove 23 and by covering the already formed upper gate electrode 10 with the polycrystalline silicon. Thus, degradation of reliability of the gate insulating film 3, as described below, can be avoided when using the silicide gate electrode.

When forming the polycrystalline silicon film so as to bury the EI groove 23 and cover the already formed upper gate electrode 10, a seam easily forms as it is formed on the groove at the portion on the EI groove 23 of the newly formed polycrystalline silicon film. When such a seam forms, the silicide material film gets into the seam when the silicide material film is formed on the newly formed polycrystalline silicon film. When the silicide material film that entered the seam contacts the lower gate electrode 4 made of polycrystalline silicon film and thermal processing is carried out in such state, the silicide material film that has got into the seam reacts with the lower gate electrode 4, thereby generating the silicide. When such silicide contacts the gate insulating film 3, properties such as the work function of the gate insulating film 3 change, and the reliability of the gate insulating film 3 degrades.

However, in the first modification of the present embodiment, the connection via 22 made from silicon is formed only in the EI groove 23 without using the above-described method, and thus the degradation of the reliability of the gate insulating film 3 can be avoided even if the silicide gate electrode is used.

In order to solve such problem, a method of forming a barrier metal in the EI groove 23 that passes through the upper gate electrode 10 and the IPD 9 and reaches the lower gate electrode 4 is considered, but the contact resistance between the upper gate electrode 10 and the lower gate electrode 4 increases if the barrier metal is formed. However, such problem does not arise according to the first modification of the present embodiment, and thus the barrier metal is not necessary and the contact resistance can be avoided from increasing.

### (Second Modification)

In the present embodiment, after forming the EI groove, the silicon is selectively solid-phase grown in the EI groove 23 to form the connection via 22. In a second modification, on the other hand, a protective film covering the side walls of the EI groove 23 is formed, and then the connection via is selectively solid-phase grown. More specifically, in the second modification, a protective film that covers the side walls of the EI groove 23 including the lower gate electrode 4 and the upper gate electrode 10 is formed, and the connection via 22 is selectively solid-phase grown on the bottom surface of the EI groove 23 including the lower gate electrode 10. The connection via 22 is thus crystal-grown first so as to cover the upper part of the side walls of the EI groove 23 including the upper gate electrode 10 and blocks the EI groove 23, and a state in which a cavity forms at the lower part of the EI groove 23, that is, a state in which the connection via 22 is not connected with the lower gate electrode 4 can be avoided.

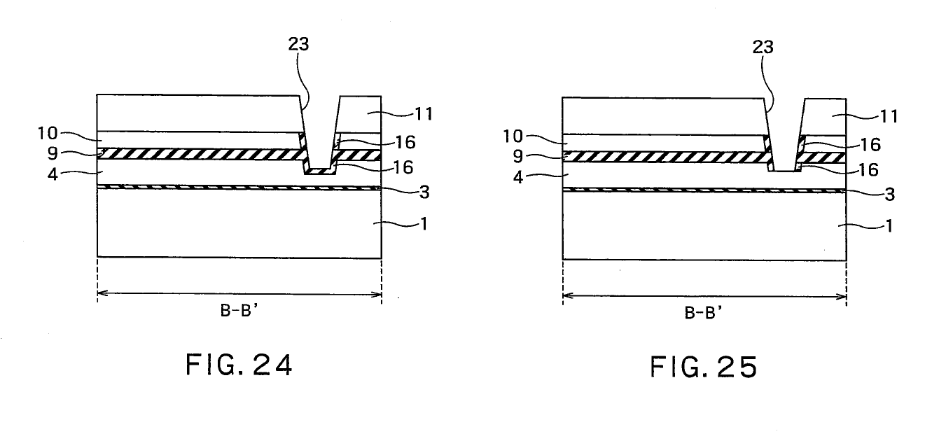

The present modification will be described with reference to FIGS. 24 to 26. FIGS. 24 to 26 are cross-sectional views corresponding to FIG. 2(b), that is line B-B′ of FIG. 1(a).

First, similar to the embodiment described above, the EI groove 23 shown in FIGS. 12(a) and 12(b) is formed. The EI groove 23 has side walls including the lower gate electrode 4, the IPD 9, the upper gate electrode 10, and the hard mask 11, and a bottom surface including the lower gate electrode 4.

As shown in FIG. 24, the surface of the side walls of the EI groove 23 including the lower gate electrode 4 and the upper gate electrode 10, and the bottom surface of the EI groove 23 including the lower gate electrode 4 are thermally oxidized to form a protective film 16 of a silicon dioxide film that covers the side walls of the EI groove 23 including the lower gate electrode 4 and the upper gate electrode 10 and the bottom surface of the EI groove 23 including the lower gate electrode. The thermal oxidation is carried out based on a known method and known conditions. The protective film 16 is preferably formed to have a thickness of equal to or more than 3 nm so as not to rip in the etching step to be carried out afterwards.

The protective film 16 covering the bottom surface of the EI groove 23 is then removed through the RIE method. Accordingly, the bottom surface of the EI groove 23 is exposed, and the side walls of the EI groove 23 including the lower gate electrode 4 and the upper gate electrode 10 is covered by the protective film 16, as shown in FIG. 25.

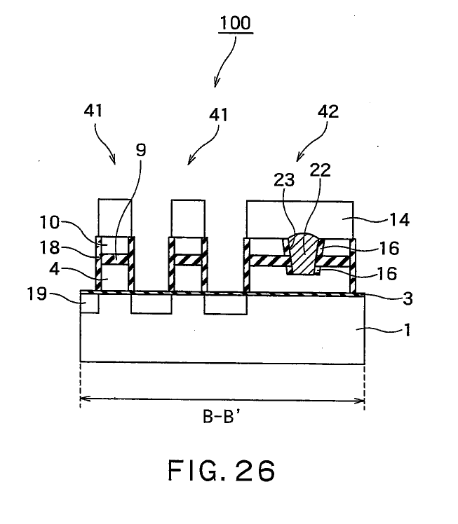

Similar to the present embodiment, dilute hydrofluoric acid treatment and cleaning are carried out to remove the processing residual, and the silicon is selectively solid-phase grown in the EI groove 23. That is, the silicon is crystal-grown while being subjected to the influence of the crystal structure of the lower gate electrode 4 of the bottom surface of the EI groove 23 to form the connection via 22 having a crystal structure that preferentially has a specific crystal orientation based on the crystal structure of the lower gate electrode 4. The subsequent steps are similar to the previously described embodiment, and hence the description will not be repeated. The NAND type flash memory 100 having a cross-sectional view shown in FIG. 26 is thereby obtained.

Therefore, according to the second modification, the protective film that covers the side walls of the EI groove 23 including the lower gate electrode 4 and the upper gate electrode 10 is formed, and the connection via 22 is selectively solid-phase grown on the bottom surface of the EI groove 23, so that the connection via 22 crystal grows first to cover the upper part of the side walls of the EI groove 23 including the upper gate electrode 10 thus blocking the EI groove 23. Accordingly, a state in which a cavity forms at the lower part of the EI groove 23, that is, a state in which the connection via 22 is not connected with the lower gate electrode 4 can be avoided.

In the second modification, the connection via 22 does not have a configuration of directly contacting the upper gate electrode 10, but the connection via 22 contacts the metal gate electrode 14 at the upper surface thereof since the metal gate electrode 14 is formed on the upper gate electrode 10 in the subsequent step. Therefore, the metal gate electrode 14 is electrically connected to the upper gate electrode 10, and the connection via 22 electrically connects the lower gate electrode 4 and the upper gate electrode 10 through the metal gate electrode 14.

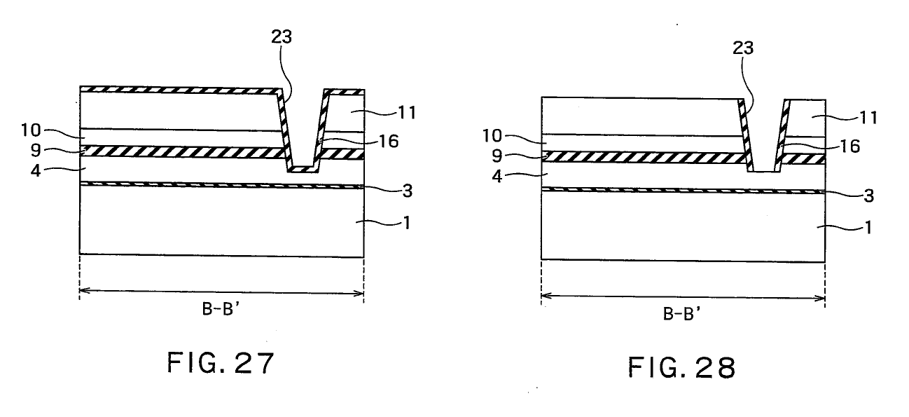

The protective film 16 in the second modification may be formed in the following manner. The method of forming the protective film 16 will be described using FIGS. 27 and 28. FIGS. 27 and 28 are cross-sectional views corresponding to FIG. 2(b), that is, line B-B′ of FIG. 1(a).

Similar to the embodiment described above, the EI groove 23 shown in FIGS. 12(a) and 12(b) is first formed.

Then, as shown in FIG. 27, the protective film 16 is formed to cover the upper surface of the hard mask 11; the side walls of the EI groove 23 including the lower gate electrode 4, the IPD 9, the upper gate electrode 10, and the hard mask 11; and the bottom surface of the EI groove 23 including the lower gate electrode 4. The protective film 16 merely needs to be an insulating film such as silicon dioxide film or silicon nitride film, and the formation of the protective film 16 may be carried out based on a known method and known conditions. The protective film 16 is preferably formed to have a thickness of equal to or more than 3 nm so as not to rip in the etching step to be carried out afterwards.

A part of the protective film 16 is then removed through the RIE method to expose the bottom surface of the EI groove 23. Therefore, as shown in FIG. 28, the protective film 16 covering the bottom surface of the EI groove 23 and the upper surface of the hard mask 11 is removed, and the protective film 16 covering the side walls including the lower gate electrode 4, the IPD 9, the upper gate electrode 10, and the hard mask 11 remain.

In the above-described embodiment, as well as first and second modifications, the silicon substrate does not necessarily be made from silicon and may be made of other materials. A semiconductor structure or the like may be formed on various substrates.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method of manufacturing a semiconductor device including a memory cell transistor in a first region of a substrate, and a select gate transistor in a second region of the substrate, the manufacturing method comprising:
forming a gate insulating film, a lower gate electrode, an inter-electrode insulating film, an upper gate electrode, and a hard mask on the substrate;
forming a groove passing through the hard mask, the upper gate electrode and the inter-electrode insulating film, and reaching the lower gate electrode in the second region of the substrate; and
forming a connection layer having a crystal structure which preferentially has a specific crystal orientation and that electrically connects between the lower gate electrode and the upper gate electrode, by being selectively crystal-grown while being subjected to an influence from a crystal structure of the lower gate electrode in the groove.

2. The method of manufacturing the semiconductor device according to claim 1, wherein
the lower gate electrode includes a polycrystalline silicon film, and
the connection layer includes a crystal film consisting of one of silicon, germanium, or a mixture thereof.

3. The method of manufacturing the semiconductor device according to claim 1, wherein forming the connection layer is carried out through a CVD method using a gas containing chlorine and hydrogen.

4. The method of manufacturing the semiconductor device according to claim 3, wherein a speed of the crystal-growth is controlled by changing an amount of chlorine in the gas.

5. The method of manufacturing the semiconductor device according to claim 1, further comprising doping one of P, As, or B in the connection layer.

6. The method of manufacturing the semiconductor device according to claim 1, further comprising forming a protective film covering the side walls of the groove, before the formation of the connection layer.

7. The method of manufacturing the semiconductor device according to claim 1, further comprising forming a metal gate electrode on the upper gate electrode and the connection layer.

8. The method of manufacturing the semiconductor device according to claim 1, further comprising forming a silicide gate electrode on the upper gate electrode and the connection layer.

9. A semiconductor device comprising a memory cell transistor in a first region of a substrate, and a select gate transistor in a second region of the substrate, wherein
the memory cell transistor includes a first gate insulating film formed on the substrate, a first lower gate electrode formed on the first gate insulating film, a first inter-electrode insulating film formed on the first lower gate electrode, and a first upper gate electrode formed on the first inter-electrode insulating film; and
the select transistor includes a second gate insulating film formed on the substrate, a second lower gate electrode formed on the second gate insulating film, a second inter-electrode insulating film formed on the second lower gate electrode, a second upper gate electrode formed on the second inter-electrode insulating film, and a connection layer having a crystal structure that preferentially has a specific crystal orientation and passes through the second inter-electrode insulating film to electrically connect the second lower gate electrode and the second upper gate electrode.

10. The semiconductor device according to claim 9, wherein the second upper gate electrode is a single layer directly arranged on the second inter-electrode insulating film.

11. The semiconductor device according to claim 9, wherein the connection layer has a crystal structure based on the crystal structure of the second lower gate electrode.

12. The semiconductor device according to claim 9, wherein an upper surface of the connection layer is in plane with an upper surface of the second upper gate electrode or is projected from the upper surface of the second upper gate electrode.

13. The semiconductor device according to claim 9, wherein the connection layer includes one of silicon, germanium, or a mixture thereof.

14. The semiconductor device according to claim 9, wherein the first and the second lower gate electrodes include polycrystalline silicon films.

15. The semiconductor device according to claim 9, wherein the connection layer includes one of P, As, B.

16. The semiconductor device according to claim 9, further comprising a metal gate electrode on the first and the second upper gate electrodes and the connection layer.

17. The semiconductor device according to claim 9, further comprising a silicide gate electrode on the first and the second upper gate electrodes and the connection layer.

18. The semiconductor device according to claim 9, further comprising a protective film covering a side walls of the groove.

19. The semiconductor device according to claim 18, wherein the protective film includes silicon dioxide film.

20. The semiconductor device according to claim 18, wherein the protective film has a film thickness of equal to or more than 3 nm.
